(19) United States
(12) Patent Application Publication
(10) Pub. No.: US 2023/0275194 A1
(43) Pub. Date: Aug. 31, 2023

(54) METHOD FOR PRODUCING A COMPONENT, AND OPTOELECTRONIC COMPONENT

(71) Applicant: OSRAM OPTO SEMICONDUCTORS GMBH, Regensburg (DE)

(72) Inventor: Matthias Hien, Kirchroth (DE)

(21) Appl. No.: 18/005,533

(22) PCT Filed: Jul. 13, 2021
(86) PCT No.: PCT/EP2021/069454

§ 371 Date: Jan. 13, 2023

(30) Foreign Application Priority Data
Jul. 15, 2020 (DE) 10 2020 118 671.1

(51) Int. Cl. H01L 33/48; H01L 25/075; H01L 25/04; H01L 31/0203; H01L 31/18; H01S 5/022; B33Y 80/00; B33Y 10/00

(52) U.S. Cl. CPC H01L 33/486; H01L 25/0753; H01L 25/042; H01L 31/0203; H01L 31/18; H01S 5/022; B33Y 80/00; B33Y 10/00; H01L 2933/0033

(57) ABSTRACT

A method for manufacturing a component is disclosed. In an embodiment a method for producing a component includes providing a connection carrier and forming a housing body on at least a part of the connection carrier by a 3D printing method, wherein forming the housing body includes applying at least one layer of a liquid potting compound, selectively curing the at least one layer of the liquid potting compound and removing residues of the liquid potting compound.

This patent application is a national phase filing under section 371 of PCT/EP2021/069454, filed Jul. 13, 2021, which claims the priority of German patent application 10 2020 118 671.1, filed Jul. 15, 2020, each of which is incorporated herein by reference in its entirety.

### TECHNICAL FIELD

A method for producing a component is provided. An optoelectronic component is furthermore provided.

### SUMMARY

Embodiments provide a method for producing a component having improved properties, for example, improved mechanical properties. Further, embodiments provide an optoelectronic component having improved properties, for example, improved mechanical properties.

The component may, for example, be an electronic component or an optoelectronic component. Optoelectronic components may comprise at least one semiconductor chip, which emits and/or receives electromagnetic radiation in a particular wavelength range. For example, the optoelectronic component is a semiconductor laser component, a light-emitting diode and/or a photodiode.

According to at least one embodiment of the method for producing a component, a connection carrier is provided.

The connection carrier is in particular a carrier for electronic devices, and is used for mechanical fastening as well as stability. Furthermore, the material of the connection carrier has a good electrical conductivity as well as a good thermal conductivity. The connection carrier is thus used for electrical and/or thermal connection, for example of a semiconductor chip.

The connection carrier is, for example, a lead frame or a circuit board. The lead frame is, in particular, configured as a solid body. The circuit board comprises an electronically insulating material with conductive connections adhering thereto, so-called circuit traces. The insulating material used may, for example, be fiber-reinforced plastic or a ceramic material. The circuit traces are formed using a metal.

According to at least one embodiment of the method, a housing body is produced on at least a part of the connection carrier by means of a 3D printing method.

The housing body is, in particular, configured as a solid body. The housing body is, for example, applied on the connection carrier. In particular, the housing body is applied directly on the connection carrier. This means that no further layer is arranged between the housing body and the connection carrier. The housing body is used, inter alia, for mechanical stabilization of the component and protects the connection carrier from mechanical and/or chemical damage.

The housing body is applied by means of the 3D printing method on at least a part of the connection carrier. During the 3D printing method, material is applied layer-by-layer so as to produce the three-dimensional housing body. The layerwise construction is in this case carried out, for example, under computer control using one or more liquid or solid materials according to predetermined dimensions and shapes. During the construction, physical or chemical curing or melting processes take place. Suitable materials for the 3D printing method for forming the housing material are plastics, synthetic resins, ceramics, carbon materials, graphite materials and metals.

According to at least one embodiment of the method for producing a component, a connection carrier is provided. A housing body is subsequently produced on at least a part of the connection carrier by means of a 3D printing method.

By means of the 3D printing method, a desired design, for example a desired shape of the housing body, may be achieved in a controlled way.

According to at least one embodiment, at least one optoelectronic semiconductor chip is applied on the connection carrier before the production of the housing body. The semiconductor chip is configured to emit and/or receive electromagnetic radiation in a particular wavelength range. For example, the semiconductor chip is configured to emit primary radiation in a first wavelength range during operation. Preferably, the semiconductor chip emits the primary radiation in the first wavelength range from a radiation exit face. In particular, the semiconductor chip emits primary radiation in the ultraviolet spectral range and/or in the visible spectral range, particularly preferably in the blue spectral range, during operation.

The semiconductor chip is for example a light-emitting diode chip or a laser diode chip. Preferably, the semiconductor chip comprises an epitaxially grown semiconductor layer sequence having an active zone, which is configured to produce primary radiation. For this purpose, the active zone comprises for example a pn junction, a double heterostructure, a single quantum well structure or, particularly preferably, a multiple quantum well structure. The semiconductor chip may for example be a flip-chip, in which the semiconductor chip comprises contacts on the same side, or it may be a semiconductor chip in which the contacts are located on opposite sides.

According to at least one embodiment, at least one cavity and/or an undercut are introduced into the housing body. The cavity and/or the undercut are, in particular, free of the housing body. The cavity and/or the undercut are filled with an ambient atmosphere, for example air, nitrogen, or with a noble gas.

The cavities may have different structures and shapes, in particular the shape of a sphere, a cuboid, a cube, a cone, a conic frustum, a cylinder, a pyramid, a pyramidal frustum or a polyhedron. For example, the cavity has the shape of a sphere or a conic or pyramidal frustum.

Some of the structures, in particular cuboid structures, may comprise supporting structures which can increase the mechanical stability of the cavity.

The cavity and/or the undercut may preferably not be formed by a shaping method, for example a foil-assisted molding method (FAM method). By the introduction of a cavity and/or an undercut, the weight of the component may advantageously be reduced and/or the center of mass of the component may be adjusted. The effect of adjusting the center of mass of the component is that further processing may be simplified and accelerated.

According to one embodiment, the cavity is configured as a closed hollow space inside the housing body. The closed hollow space is in this case, in particular, free of material of the housing body and bounded by the housing body on all sides. The closed hollow space is for example filled with an ambient atmosphere, for example air, nitrogen, or with a noble gas, and may for example have the shape of a polyhedron. Preferably, the closed hollow space has a top face which is formed parallel to the layers of which the housing body consists.

According to at least one embodiment, the housing body is formed as follows:
applying at least one layer of a liquid potting compound,
selectively curing the at least one layer of the liquid potting compound,
removing residues of the liquid potting compound.

In a first step, a layer of a liquid potting compound is applied. The liquid potting compound comprises a material from the following group: initiator, epoxide, vinyl ester resin, titanium dioxide, silicone and/or acrylate. For example, onium salts may be used as initiators. The material is preferably readily polymerizable, the material being for example a light-curing resin, and also transmissive for electromagnetic radiation. The layer of the liquid potting compound is applied on the connection carrier and/or semiconductor chip. Preferably, the layer of the liquid potting compound is applied directly on the connection carrier and/or semiconductor chip.

Subsequently, the layer of the liquid potting compound is selectively cured. This means that the initiator of the liquid potting compound is activated in order to start a polymerization of the liquid potting compound. By the activation of the initiator, a part of the liquid potting compound is selectively cured. Then, for example, the liquid uncured potting compound is removed. For example, the removal of the liquid uncured potting compound is carried out by taking the housing body to be constructed out from the solution of the liquid potting compound. The liquid uncured potting compound is therefore removed by gravity.

Next, for example, a further layer of the liquid potting compound is applied. In particular, the further layer is applied onto the already cured layer and/or semiconductor chip. The further layer of the liquid potting compound is likewise selectively cured. This method is repeated until a desired thickness is reached. For example, the method is repeated from ten to twenty times. This means that preferably at least ten to at most twenty layers of a liquid potting compound are applied and then successively cured layer-by-layer. The individual layers are joined to the housing body via covalent bonds. Each of the individual layers has a thickness of from at least 10 micrometers to at most 20 micrometers.

During the application of the layers and/or subsequently, residues of the liquid potting compound are removed. This means that the part of the liquid potting compound which is not cured may be removed. The removal is carried out, for example, by washing.

In a last step, final curing optionally takes place in a chamber, for example in an oven or a UV chamber. The final curing takes place in particular optically with blue and/or UV light in a UV chamber. In this way, the housing body is fully solidified and is joined to the semiconductor chip and/or connection carrier.

In particular, the housing body is formed using one of the following methods: top-down method, bottom-up method or CLIP (Continuous Liquid Interface Production) method.

In the top-down method, the housing body to be constructed is contained in a solution of the liquid potting compound throughout the entire method. With the top-down method, housing bodies may advantageously be produced very rapidly.

In the bottom-up method and the CLIP method, the housing body to be constructed is taken out from the solution of the liquid potting compound after each selective curing step. In particular, the bottom-up method and the CLIP method are suitable for producing the cavity and/or undercuts. With these methods, cavities and/or undercuts which are free of the material of the housing body, in particular free of the liquid uncured potting compound, may advantageously be produced particularly easily.

In the aforementioned FAM method, conversely, the surface is sealed before injecting a potting compound. Cavities and/or undercuts cannot be formed with the FAM method.

One advantage of the method described here is that the liquid potting compound is cured only where it is actually needed. A desired design of the housing body may thereby be achieved.

According to at least one embodiment, the curing of the liquid potting compound is carried out by selective exposure with an electromagnetic radiation source. The electromagnetic radiation source is, in particular a light source. The light source may be a laser source or a mercury vapor lamp. Furthermore, the liquid potting compound may be cured by using an optical element such as a digital mask or a digital micromirror. The electromagnetic radiation source is arranged in such a way, and the electromagnetic radiation is shaped, deviated or selectively absorbed by using the optical element in such a way, that the liquid potting compound is selectively exposed so as to cure the liquid potting compound precisely at the exposed position.

The geometry and the design of the housing body are adjusted in particular by using a computer-aided design (CAD). The CAD is converted into stereolithography files and software such as Cura creates the necessary G-code in order to generate the individual layers. Positions at which the liquid potting compound is exposed in order to produce the housing body with the desired geometry and the desired design are thereby predetermined.

According to at least one embodiment, the curing of the liquid potting compound is carried out by means of a laser. The laser may be aimed directly onto the liquid potting compound and therefore start the initiation of the polymerization for curing the liquid potting compound. In this context, directly may mean that the laser beam is not deviated, although it may travel through optical elements such as lenses or windows. Alternatively, the laser may be deviated by means of a galvanometer. In this case, the selected positions of the liquid potting compound are exposed and cured in a controlled way. The method with exposure of the liquid potting compound by means of the laser has a good resolution since the laser can be focused particularly well. In particular, the accuracy of the laser method lies between at least 100 nanometers and at most 30 micrometers. Preferably, the accuracy of the laser method lies between at least 100 nanometers and at most 10 micrometers.

According to at least one embodiment, the curing of the liquid potting compound is carried out by using a digital mirror device. The digital mirror device (DMD) is a microelectromechanical component for the dynamic modulation of light. With digital mirror devices, distinction is made between so-called microscanners and spatial light modulators.

In the case of microscanners, the modulation of a beam of rays is carried out on a continuously moved individual mirror. Light for the exposure may be guided, or scanned, in strips over the liquid potting compound.

In the case of spatial light modulators, the modulation of the light is carried out by means of a mirror matrix. The individual mirrors assume discrete deflections in the course of time. In this way, the deviation of partial beams, or a phase-shifting effect, is achieved. With the aid of a matrix arrangement, digital mirror devices can deviate the light of a strong light source in such a way that an image is projected. In this way, relatively large areas of the liquid potting compound may be exposed in a controlled way.

This means that a light source radiates onto a digital mirror device, and is then reflected and impinges on the liquid potting compound, for example via a lens. As soon as the electromagnetic radiation of the light source impinges on the liquid potting compound, the latter is cured at the particular position. In comparison with curing of the liquid potting compound by means of a laser, curing of the liquid potting compound by using a digital mirror device takes place by simultaneous exposure of a particular layer. The method therefore has a high speed.

According to at least one embodiment, the cavity and/or the undercut are formed at unexposed positions. This means that positions which are not exposed, or are free of the exposure, form the cavity and/or the undercut. The liquid potting compound is cured at controlled positions by exposure, while the positions which are not exposed are not cured and form the cavity and/or the undercut. The uncured liquid potting compound is removed from the component, for example by washing. Alternatively, the uncured liquid potting compound may flow out from the cavity by gravity. This is the case, for example, in the bottom-up method and the CLIP method.

According to at least one embodiment, at least two semiconductor chips are applied on the connection carrier before the production of the housing body. In particular, a multiplicity of semiconductor chips are applied on the connection carrier.

According to at least one further embodiment, the connection carrier remains free of the housing body in a free region between two adjacent semiconductor chips. The component may therefore advantageously be singulated between two adjacent semiconductor chips in a simplified way. Since the housing body is not arranged on the connection carrier and does not need to be sawed during the singulation of the semiconductor chips, no cracks are formed in the housing body. Singulation by means of sawing is carried out merely through the connection carrier, for example through copper connecting bars. The free region between two directly adjacent semiconductor chips is between at least 50 micrometers and at most 250 micrometers, for example between at least 50 micrometers and at most 150 micrometers.

An optoelectronic component is furthermore provided. In particular, an optoelectronic component as described here may be produced by the described method for producing the component. This means that all features which are disclosed for the method for producing the component are also disclosed for the optoelectronic component, and vice versa.

According to at least one embodiment, the optoelectronic component comprises a connection carrier. The connection carrier is, for example, a lead frame or a circuit board.

According to at least one further embodiment, the optoelectronic component comprises a semiconductor chip. The semiconductor chip comprises a radiation exit face, for example, and is then provided to emit primary radiation of a first wavelength range during operation.

According to at least one embodiment, the optoelectronic component comprises a housing body which encloses the connection carrier and the semiconductor chip in some positions. The housing body is, in particular, arranged directly on the connection carrier and/or the semiconductor chip.

According to at least one embodiment, the optoelectronic component comprises a housing body which has at least one cavity and/or undercut. In particular, the cavity and/or the undercut are free of the housing body. In particular, the cavity and/or undercut are filled with a gas. The cavity and/or undercut are, for example, filled with an ambient atmosphere. With the aid of the cavity and/or undercut, the center of mass of the optoelectronic component may be adjusted particularly well.

According to at least one embodiment, the optoelectronic component comprises a connection carrier, a semiconductor chip and a housing body, which encloses the connection carrier and the semiconductor chip in some positions, the housing body comprising at least one cavity and/or undercut.

According to at least one embodiment, the semiconductor chip is fastened on the connection carrier by means of an adhesive layer. The semiconductor chip may therefore advantageously be fixed in a desired position.

According to at least one embodiment, the housing body fully encloses the semiconductor chip laterally. In particular, the housing body is in direct contact with the semiconductor chip in some positions. The housing body may be connected to the semiconductor chip. In particular, all sides of the semiconductor chip which extend perpendicularly or transversely with respect to a main plane of extent of the device are enclosed by the housing body. Moisture between the semiconductor chip and the housing body may thereby be prevented or reduced.

According to at least one embodiment, the housing body protrudes by at most 20 micrometers beyond the semiconductor chip in a vertical direction, which extends perpendicularly to the main plane of extent of the component. Preferably, the housing body protrudes beyond the semiconductor chip by at most 10 micrometers. By the protrusion of the housing body beyond the semiconductor chip, the semiconductor chip is preferably protected from external influences. For example, the semiconductor chip does not project beyond the housing body in the vertical direction.

According to at least one embodiment, the side of the semiconductor chip facing away from the connection carrier is free of the housing body. This means, for example, that the radiation exit face of the semiconductor chip is free of the housing body. Optionally, a conversion element may be arranged on the radiation exit face of the semiconductor chip.

According to at least one embodiment, a thickness of the housing body lies between at least 100 micrometers and at most 2000 micrometers. In particular, a thickness of the housing body lies between at least 100 micrometers and at most 400 micrometers, for example between at least 150 micrometers and at most 250 micrometers.

According to at least one embodiment, the housing body comprises a material from the following group: polymerized epoxide, polymerized acrylate, vinyl ester resin, titanium dioxide, silicone, initiators and combinations thereof. In particular, a housing body is produced using titanium dioxide by means of plasma coating.

One concept of the present method for producing a component is that the component geometries may be defined in a computer-aided design.

Furthermore, no restriction is required for the tooling, which for example needs to be established for each individual design in the case of a FAM method. The component geometries furthermore do not need to be flat, as in the case of the FAM method.

Owing to the formation of cavities and/or undercuts in the component, less material is advantageously required since it is used only at the positions where it is needed.

Furthermore, the center of mass of the component may be adjusted in such a way that subsequent use of the components, or arrangement of the components, is facilitated.

### BRIEF DESCRIPTION OF THE DRAWINGS

Further advantageous embodiments and developments of the method for producing a component and of the optoelectronic component may be found from the exemplary embodiments described below in connection with the figures, in which:

FIG. 1 shows a schematic sectional representation of a method for producing a component according to one exemplary embodiment;

FIG. 2 shows a schematic sectional representation of a method for producing a component according to one exemplary embodiment;

FIG. 3 shows a schematic sectional representation of an optoelectronic component according to one exemplary embodiment; and

FIG. 4 shows a plan view of a multiplicity of optoelectronic components according to one exemplary embodiment.

### DETAILED DESCRIPTION OF ILLUSTRATIVE EMBODIMENTS

Elements which are the same or similar, or which have the same effect, are provided with the same references in the figures. The figures and the size proportions of the elements represented in the figures with respect to one another are not to be regarded as true to scale. Rather, individual elements, in particular layer thicknesses, may be represented exaggeratedly large for better representability and/or for better understanding.

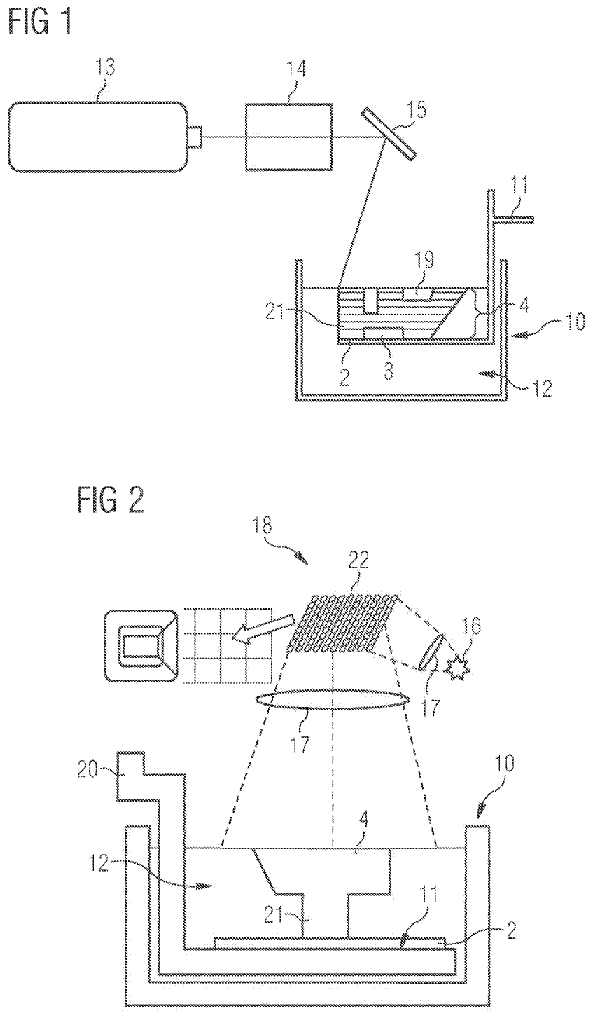

In the method for producing a component according to the exemplary embodiment of FIG. 1, a connection carrier 2 is provided in a first step. The connection carrier 2 is arranged on a platform it The platform 11 and the connection carrier 2 are located in a container 10.

A liquid potting compound 12 is introduced into the container 10. The liquid potting compound 12 comprises for example an epoxide, an acrylate, a vinyl ester resin, titanium dioxide, a silicone and/or a co-initiator.

The connection carrier 2 on the platform 11 is initially located at the surface of the liquid potting compound 12. The connection carrier 2 is arranged on the platform 11, and there is a layer 21 of the liquid potting compound 12 on the connection carrier 2.

The layer 21 of the liquid potting compound 12 is cured by means of a laser 13. The electromagnetic radiation of the laser 13 is radiated onto an optical unit 14, for example a mirror, which is then directed in a controlled way onto a particular position of the layer 21 by means of a galvanometer 15. Particular regions of the layer 21 may therefore be cured in a controlled way.

The curing is carried out layerwise. Once the layer 21 has been cured as desired, the platform 11 is moved further into the liquid potting compound 12 and the further layer 21 is cured in a controlled way by means of the laser 13. This is carried out until a multiplicity of layers 21 have been cured. In the exemplary embodiment of FIG. 1, for example, 20 layers 21 each with a thickness of 10 micrometers are cured layerwise. The cured layers 21 establish covalent bonds with one another and form the housing body 4.

At the positions which are not exposed by the laser 13, the liquid potting compound 12 is not cured and a cavity 19 and/or an undercut is formed. The liquid potting compound 12 which is not cured is removed. The method according to FIG. 1 has a very good resolution since the individual layers 21 can be irradiated with the aid of the laser 13, and therefore cured, in a controlled way.

Optionally, at least one semiconductor chip 3 may be applied on the connection carrier 2. The semiconductor chip 3 is applied on the connection carrier 2 before the housing body 4 is formed.

The method of the exemplary embodiment of FIG. 2 for producing a component comprises a container 10, in which a Z stage 20 and a platform 11 are arranged. The connection carrier 2 is arranged on the platform 11. The container 10 comprises a liquid potting compound 12.

According to this exemplary embodiment as well, the connection carrier 2 is initially located on the platform 11, close to the surface of the liquid potting compound 12. A layer 21 of the liquid potting compound 12 is arranged on the connection carrier 2. The layer 21 of the liquid potting compound 12 is selectively cured by exposure using an electromagnetic radiation source. After the layer 21 has been selectively cured, the platform 11, or the Z stage 20, is moved a little further into the liquid potting compound 12. The further layer 21 is located on the already cured potting compound and is in turn cured by the selective exposure using an electromagnetic radiation source.

The curing of the liquid potting compound 12 is carried out by using a digital mirror device 18. In this case, the electromagnetic rays of a light source 16 are deviated onto a multiplicity of mirrors 22, and then impinge on the liquid potting compound 12 via a lens 17. According to the exemplary embodiment of FIG. 2, for example, 20 layers 21 each with a thickness of 10 micrometers are successively cured layerwise. The individual layers 21 then bond to form a housing body 4. The positions which are unexposed form the cavity 19 and/or the undercut of the housing body 4.

The methods of FIGS. 1 and 2 show the production of components according to the top-down method. The components according to embodiments of the invention may similarly also be produced according to the bottom-up method and the CLIP (not shown here).

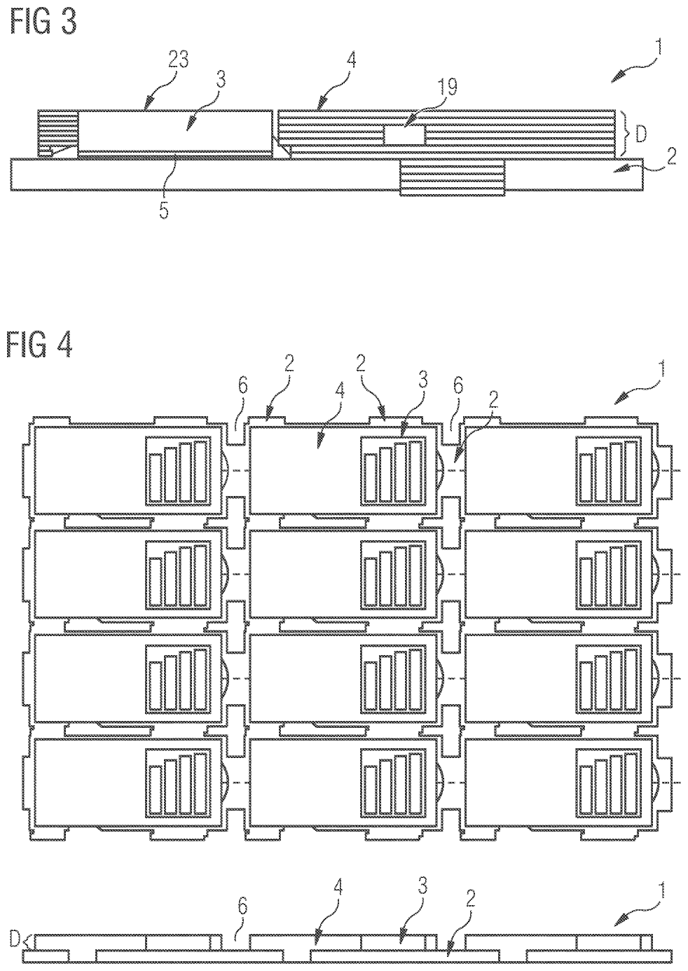

The exemplary embodiment of FIG. 3 shows an optoelectronic component 1. The optoelectronic component 1 comprises a connection carrier 2, a semiconductor chip 3 and a housing body 4. The housing body 4 encloses the connection carrier 2 and the semiconductor chip 3 in some positions. Furthermore, the housing body 4 comprises at least one cavity 19. In the exemplary embodiment of FIG. 3, the cavity 19 is configured as a closed hollow space and has a cuboid structure. Alternatively, the cavity 19 may also have the shape of a sphere, a cube, a cone, a conic frustum, a cylinder, a pyramid, a pyramidal frustum or a polyhedron (not shown here). The cavity is, in particular, free of material of the housing body and bounded by the housing body on all sides.

The semiconductor chip 3 is optionally fastened on the connection carrier 2 by means of an adhesive layer 5. Preferably, the semiconductor chip 3 is enclosed laterally by the housing body 4. The housing body 4 is for example connected to the semiconductor chip 3, at least arranged as tightly as possible on the semiconductor chip 3, in order to reduce or prevent moisture between the semiconductor chip 3 and the housing body 4.

FIG. 3 additionally shows that the side of the housing body 4 which faces away from the connection carrier 2 ends flush with the semiconductor chip 3. The radiation exit face 23 of the semiconductor chip 3 is therefore free of the housing body 4. Optionally, it is possible for the housing body 4 to protrude by at most 20 μm beyond the semiconductor chip 3. A thickness D of the housing body 4 is 200 μm. In this case, 20 layers 21 each with a thickness of 10 μm were applied. In the finished optoelectronic component 1, the housing body 4 merely comprises one continuous layer 21, since the 20 layers 21 establish covalent bonds with one another. The material of the housing body 4 is a polymerized epoxide.

The exemplary embodiment of FIG. 4 shows a plan view of a multiplicity of optoelectronic components 1. Each optoelectronic component 1 comprises a connection carrier 2, a semiconductor chip 3 and a housing body 4, which encloses the connection carrier 2 and the semiconductor chip 3 in some positions. A free region 6 of the connection carrier 2, which is located between the semiconductor chips 3, is in this case free of the housing body 4. This has the advantage that the singulation of the multiplicity of semiconductor chips 3 is simplified, since only the connection carrier 2 needs to be sawed through. No cracks are therefore formed in the housing body 4.

The features and exemplary embodiments described in connection with the figures may be combined with one another according to further exemplary embodiments, even if not all combinations are explicitly described. Furthermore, the exemplary embodiments described in connection with the figures may alternatively or additionally comprise further features according to the description in the general part.

The description with the aid of the exemplary embodiments does not restrict the invention to this description. Rather, the invention comprises any new feature and any combination of features, which in particular includes any combination of features in the patent claims, even if this feature or this combination is not itself explicitly specified in the patent claims or the exemplary embodiments.

In the claims:

1.-15. (canceled)

16. A method for producing a component, the method comprising:
providing a connection carrier; and
forming a housing body on at least a part of the connection carrier by a 3D printing method, wherein forming the housing body comprises:
applying at least one layer of a liquid potting compound;
selectively curing the at least one layer of the liquid potting compound; and
removing residues of the liquid potting compound.

17. The method of claim 16, further comprising applying at least one optoelectronic semiconductor chip on the connection carrier before forming the housing body.

18. The method of claim 16, further comprising introducing at least one cavity and/or an undercut into the housing body.

19. The method of claim 18, wherein the cavity and/or the undercut are formed at unexposed positions.

20. The method of claim 16, wherein curing of the liquid potting compound is carried out by selective exposure with an electromagnetic radiation source.

21. The method of claim 16, wherein curing of the liquid potting compound is carried out by a laser.

22. The method of claim 16, wherein curing of the liquid potting compound is carried out by using a digital mirror device.

23. The method of claim 16, further comprising applying at least two semiconductor chips on the connection carrier before forming the housing body, wherein the connection carrier remains free of the housing body in a free region between two adjacent semiconductor chips.
